(19) United States
(12) Patent Application Publication
(10) Pub. No.: US 2026/0033349 A1
(43) Pub. Date: Jan. 29, 2026

(54) METHODS AND SYSTEMS FOR FABRICATING A WETTABLE SIDEWALL FOR A LEAD

(71) Applicant: SEMICONDUCTOR COMPONENTS INDUSTRIES, LLC, Scottsdale, AZ (US)

(72) Inventors: Rennier Sarmiento RODRIGUEZ, Calamba City (PH); Donza Valencia PUNZALAN, General Mariano Alvarez (PH); Yang CAMPOS, Cavite (PH); Joe-Ann Feive LOPEZ, Binan City (PH)

(73) Assignee: SEMICONDUCTOR COMPONENTS INDUSTRIES, LLC, Scottsdale, AZ (US)

(21) Appl. No.: 18/784,258

(22) Filed: Jul. 25, 2024

(51) Int. Cl. H01L 23/495; H01L 23/00; H01L 23/31

(52) U.S. Cl. CPC H01L 23/49551; H01L 23/3107; H01L 24/48; H01L 23/49582; H01L 2224/48175; H01L 2924/1711

(57) ABSTRACT

Implementations of a semiconductor package may include one or more leads operatively coupled with one or more semiconductor devices; and a mold compound coupled to the one or more leads and exposing a flank of the one or more leads through a surface of the mold compound that may be oriented substantially perpendicularly to a longest length of the one or more leads. An exposed surface of the flank may be recessed into the surface of the mold compound. The exposed surface of the flank may include at least one curve.

### BACKGROUND

### 1. Technical Field

Aspects of this document relate generally to semiconductor packages. More specific implementations involve leadless semiconductor packages.

### 2. Background

Semiconductor packages have been devised that allow for the protection of semiconductor devices from shock, vibration, or electrostatic discharge. Semiconductor packages can also employ additional internal structure that performs electrical routing between the semiconductor device and a motherboard or other circuit board to which the semiconductor package is attached.

### SUMMARY

Implementations of a semiconductor package may include one or more leads operatively coupled with one or more semiconductor devices; and a mold compound coupled to the one or more leads and exposing a flank of the one or more leads through a surface of the mold compound that may be oriented substantially perpendicularly to a longest length of the one or more leads. An exposed surface of the flank may be recessed into the surface of the mold compound. The exposed surface of the flank may include at least one curve.

Implementations of a semiconductor package may include one, all, or any of the following:

The at least one curve may be adjacent to a plated surface of the lead facing the one or more semiconductor devices.

The at least one curve may include an electroplated layer thereon.

The surface of the lead opposing a surface of the lead facing the one or more semiconductor devices may include an electroplated layer thereon.

The exposed surface of the flank may be completely covered by an electroplated layer thereon.

The electroplated layer of the surface of the lead opposing the surface of the lead facing the one or more semiconductor devices may extend toward the surface of the mold compound further than the electroplated layer of the surface of the lead opposing the one or more semiconductor devices extends toward the surface of the mold compound.

An electroplated layer extending across the exposed surface of the flank may form a first flange on one side of the flank and a second flange on an opposing side of the flank.

An electroplated layer extending across the exposed surface of the flank may form a flange on one side of the flank.

Implementations of a method of forming a wettable flank for a semiconductor package may include providing one or more leads operatively coupled with one or more semiconductor devices; coupling a mold compound over the one or more leads; exposing a portion of a leadframe through an opening in a first electroplated layer included on the leadframe; and forming an exposed flank of the one or more leads through etching a thickness of the leadframe to a second electroplated layer included on the leadframe. The method may include forming a third electroplated layer completely over the exposed flank of the one or more leads.

Implementations of a method of forming a wettable flank may include one, all, or any of the following:

Forming the exposed flank further may include recessing the exposed flank relative to a surface of the mold compound through the etching.

Forming the third electroplated layer completely over the exposed flank further may include forming at least one flange in the third electroplated layer.

Forming the exposed flank further may include forming at least one least one curve in the exposed flank.

The method may include forming two or more semiconductor packages by singulating the mold compound and the second electroplated layer.

The second electroplated layer may form a tie bar to the one or more leads during the forming of the third electroplated layer.

Implementations of a method of forming a wettable flank for a semiconductor package may include providing one or more leads operatively coupled with one or more semiconductor devices; coupling a mold compound over the one or more leads; masking an exposed portion of a leadframe with a masking layer; and forming a first electroplated layer on the exposed portion of the leadframe. The method may include removing the masking layer; forming an exposed flank of the one or more leads through etching a thickness of the leadframe to a second electroplated layer included on the leadframe; and forming a third electroplated layer completely over the exposed flank of the one or more leads.

Implementations of a method of forming a wettable flank for a semiconductor package may include one, all, or any of the following:

Forming the exposed flank further may include forming two curves in the exposed flank.

Forming the third electroplated layer completely over the exposed flank further may include forming two flanges in the third electroplated layer.

Forming the exposed flank further may include recessing the exposed flank relative to a surface of the mold compound through the etching.

The method may include forming two or more semiconductor packages by singulating the mold compound and the second electroplated layer.

The second electroplated layer may form a tie bar to the one or more leads during the forming of the third electroplated layer.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a perspective view of an implementation of a semiconductor package;

FIG. 2 is a top down view of a bottom surface (circuit board facing surface) of an implementation of a first leadframe;

FIG. 3 is a top down view of a bottom surface (circuit board facing surface) of an implementation of a second leadframe;

FIG. 4 is a top down view of a top surface (semiconductor die facing surface) of an implementation of the leadframe of FIG. 3;

FIG. 5 is a cross sectional view of an implementation of a leadframe following application of a mold compound thereto;

FIG. 6 is a cross sectional view of the implementation of the leadframe of FIG. 5 following etching of a thickness of the leadframe;

FIG. 7 is a cross sectional view of the implementation of the leadframe of FIG. 6 following electroplating of a third electroplated layer over exposed flanks of the leads;

FIG. 8 is a cross sectional view of the implementation of the leadframe of FIG. 7 following singulation of the mold compound and a second electroplated layer to form two semiconductor packages;

FIG. 9 is a detail cross sectional view of a flank of a lead;

FIG. 10 is a detail perspective view of a flank of a lead;

FIG. 11 is a detail perspective view of a lead showing a solder fillet that covers substantially 100% of the surface of a flank of the lead;

FIG. 12 is a cross sectional view of an implementation of a leadframe following application of a mold compound thereto;

FIG. 13 is a cross sectional view of the implementation of the leadframe of FIG. 12 following masking with a masking layer;

FIG. 14 is a cross sectional view of the implementation of the leadframe of FIG. 13 following electroplating of a first electroplated layer;

FIG. 15 is a cross sectional view of the implementation of the leadframe of FIG. 14 following removal of the masking layer;

FIG. 16 is a cross sectional view of the implementation of the leadframe of FIG. 15 following etching of a thickness of the leadframe;

FIG. 17 is a cross sectional view of the implementation of the leadframe of FIG. 16 following electroplating a third electroplated layer over exposed flanks of the leads;

FIG. 18 is a cross sectional view of the implementation of the leadframe of FIG. 17 following singulating of the mold compound and a second electroplated layer of the leadframe;

FIG. 19 is a detail cross sectional view of a flank of a lead;

FIG. 20 is a detail perspective view of a flank of a lead; and

FIG. 21 is a perspective view of a semiconductor package implementation.

### DESCRIPTION

This disclosure, its aspects and implementations, are not limited to the specific components, assembly procedures or method elements disclosed herein. Many additional components, assembly procedures and/or method elements known in the art consistent with the intended semiconductor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor packages, and implementing components and methods, consistent with the intended operation and methods.

Various semiconductor package designs employ leads to assist with routing electrical signals to and from one or more semiconductor die included in the package to a circuit or motherboard to which the semiconductor package is attached. These semiconductor packages are referred to a leaded packages or leadless, or no-leads packages. An example of a leadless package type is a quad flat no leads package (QFN). While the term “no-leads” would ordinarily suggest that the semiconductor package does not actually have any leads used for electrical routing, what is actually meant is that none of the leads actually extend beyond a molding compound used to enclose the semiconductor die and other package components. This use of the term “no-leads” is intended to contrast with the readily observable leads of leaded packages which extend outside the package outline. Thus, as used herein, a “no-leads” package includes leads, but these leads do not extend substantially beyond a surface of a mold compound used to enclose the leads.

As part of the process of attaching/coupling a semiconductor package to a circuit board or motherboard, solder materials are often used. Where soldering is employed, the ability to cause the solder to bond along the flank of a lead in addition to the surface of the lead facing the circuit board/motherboard can improve long term reliability. The presence of solder on the flank of a lead also can aid optical inspection systems' ability to determine whether an effective solder bond has been formed between the lead and the circuit board/motherboard. Both of these observations may apply whether the semiconductor package is leaded or leadless/no-leads. While the discussion and implementations disclosed in this document are discussed in the context of no-leads packages, the principles could also be adapted for flanks of leaded packages.

The height of the solder along the flank of a lead or the total percentage of the flank that is covered by solder after the bonding process with the circuit board/mother board can affect the strength of the bond and/or the reliability of the bond as well. One of the factors that prevents 100% coverage or near 100% coverage (substantially 100% coverage) of the flank is that the flank of the lead in various semiconductor package manufacturing processes is the exposed metal of the lead itself (or leadframe, if the lead is part of a leadframe). Where the lead is part of a leadframe, the lead is typically cut following application of a mold compound over the semiconductor package either to singulate the semiconductor package or in preparation for singulation. Since this typically occurs late in the process, there is not an electrical connection available to the flank of the lead after the singulation of the lead to allow the flank to be electroplated with a more solder-friendly material (which would increase the wetting of the flank). Also, because the cutting of the lead often takes place through or directly adjacent to the mold compound, the material of the flank of the lead smears into the material of the mold compound, forming a burr with a roughened edge. This now roughened flank is less able to facilitate wicking of the solder material up and along it, thus reducing the percentage of the flank that can be covered by the solder.

The various semiconductor package implementations and methods of forming semiconductor packages disclosed herein can be used for a wide variety of semiconductor device types and configurations. By non-limiting example, a wide variety of semiconductor substrates for the semiconductor die can be employed, including silicon, silicon carbide, silicon-on-insulator, glass, ruby, sapphire, gallium arsenide, or other semiconductor material types. A wide variety of semiconductor device types can be employed, including, by non-limiting example, diodes, metal oxide field effect transistors (MOSFETs), insulated gate bipolar transistors (IGBTs), power semiconductor devices, high electron mobility transistors (HEMTs), thyristors, rectifiers, or any other semiconductor device type. Any semiconductor package that employs leads that can be plated with a solder wettable material could implement the principles disclosed herein. The method implementations may be applicable where leadframes are used to support the leads during semiconductor package formation. Also, any method that can be used to attach the semiconductor die with the rest of the semiconductor package may be employed in various implementations consistent with the material of the semiconductor substrate, including, by non-limiting example, sintering, die attach films, soldering, gluing, die bonding, or any other method of forming a bond with the semiconductor substrate material. Finally, while in this document a singular semiconductor die is typically referred to, this is only for the purposes of more concise discussion since more than two semiconductor die could be included in the semiconductor package in any of a wide variety of configurations, including stacked, adjacent, overlapping, aligned, or interlocking.

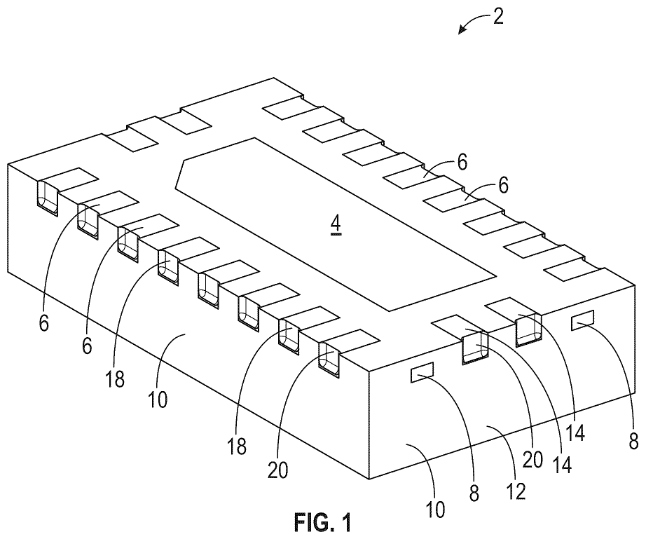

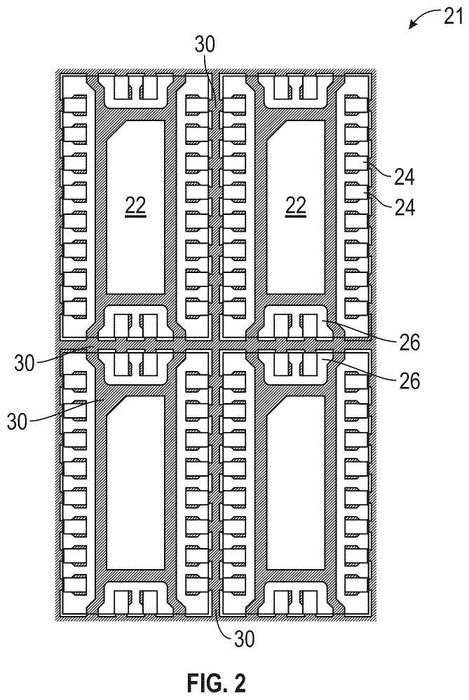

Referring to FIG. 1, an implementation of a semiconductor package 2 is illustrated that is a no leads package design. This semiconductor package 2 includes die flag 4 and a plurality of leads 6 with locations of tie bars 8 extending to the surface 10 of a mold compound 12 that encloses surfaces of the leads and leaves at least one surface 14 of the leads 6 exposed in addition to the flank 18. As illustrated in FIG. 2, the exposed surface 20 of each flank 18 is recessed into the surface/located below a plane formed by the surface 10 of the mold compound 12. Any of a wide variety of mold compound types could be employed in the various semiconductor package implementations, including, by non-limiting example, epoxies, resins, polymers, colorants, fillers, polyimides, or any other mold compound type or component. The presence of the leads 6, tie bars 8, and the die flag 4 indicates that these were each components of a leadframe originally used to allow the components of the semiconductor package to be connected with each other prior to application of the mold compound.

Referring to FIG. 2, a top view of a bottom (circuit board/motherboard facing side) of a first implementation of a leadframe 21 is illustrated. This particular leadframe is in a 4-up configuration where the leadframe components for four semiconductor packages are coupled together during processing that adds any semiconductor die and another active or passive components. Die flags 22, leads 24, and tie bars 26 are all illustrated and set off by the shaded regions in FIG. 2 used to show half etched portions 30 of the leadframe 21. Because the half etched regions are present between the leads 24, during manufacture, the remaining thickness of the leadframe is then cut following application of the mold compound, which results in the smearing effect and prevents the now electrically isolated leads from being able to have a solder wettable material electroplated on to their flanks.

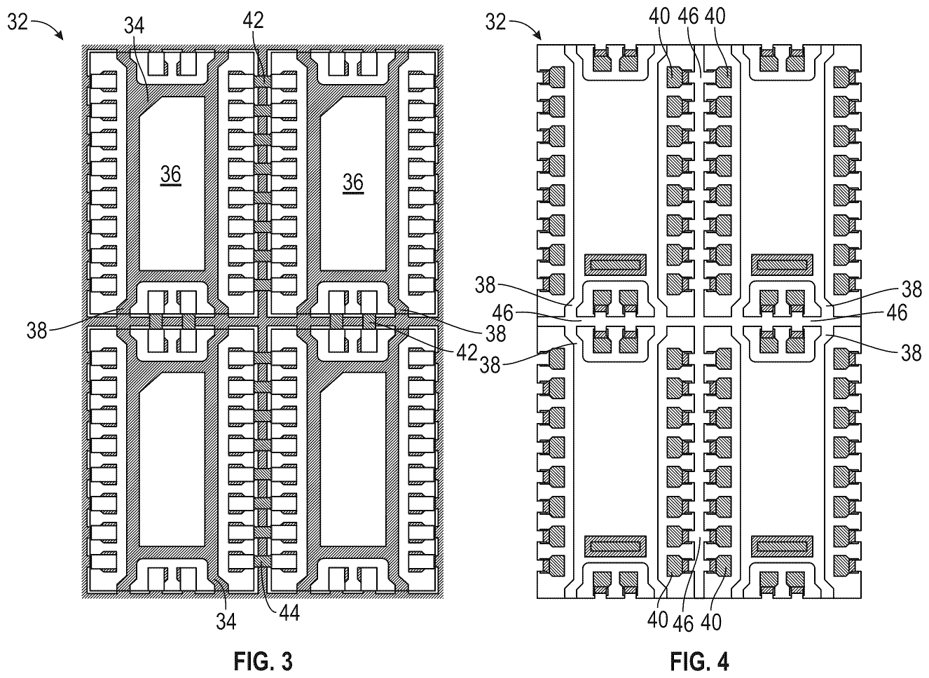

Referring to FIG. 3, a top view of a bottom of a second implementation of a leadframe 32 is illustrated. In this implementation, half etched portions 34 in the hashed areas are again present between the die flags 36 and tie bars 38 which have all been electroplated with a first electroplated layer. However, in the regions directly between the leads 40, exposed regions 42 of the material of the leadframe (copper in this implementation) are remaining and are not electroplated with the first electroplated layer. FIG. 4 illustrates a top view of a top (semiconductor die facing) side of the leadframe 32 of FIG. 3. Here this figure illustrates a second electroplated layer 46 that is present in the regions 48 between the leads 40 and tie bars 38, which will be subsequently used during later processing as described herein.

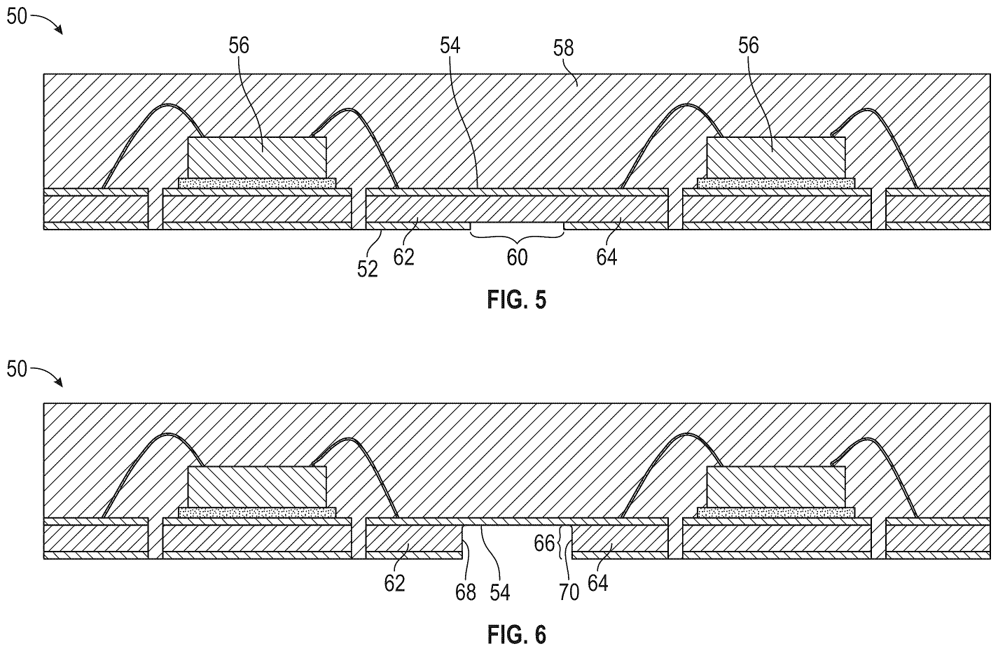

Referring to FIG. 5, a cross sectional view of a leadframe 50 is illustrated following formation of a first electroplated layer 52, a second electroplated layer 54, bonding semiconductor die 56 thereon, wirebonding, and application of mold compound 58 over the leadframe 50. The leadframe 50 is also illustrated following formation of opening 60 in the material of the first electroplated layer 52 between leads 62, 64 that leaves the material of the leadframe 50 exposed. The material of the leadframe 50 has a thickness and is composed of any of a wide variety of materials, including, by non-limiting example, copper, copper alloys, aluminum, aluminum alloys, nickel, nickel alloys, any combination thereof, or any other desired metallic material.

Referring to FIG. 6, a cross sectional view of the leadframe 50 of FIG. 5 is illustrated following removal of the exposed material across the thickness 66 of the material down to the second electroplated layer 54. The removal of the exposed material may take place using, by non-limiting example, etching, wet etching, dry etching, spray etching, any combination thereof, or any other removal technique capable of removing the material of the leadframe. Because this removal technique is selective or at least partially selective to the exposed material and not the material of the first or second electroplated layers 52, 54, respectively, the exposed material is removed preferentially. At this point, flanks 68, 70 are created for leads 64, 62, respectively, which have a height of the thickness 66.

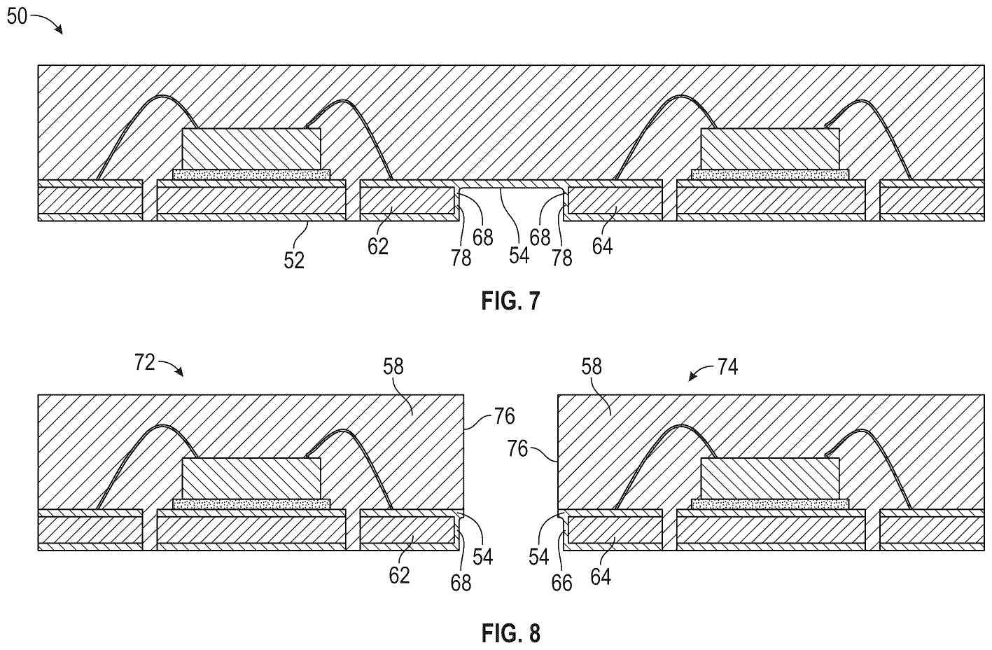

Referring to FIG. 7, the leadframe 50 of FIG. 6 is illustrated following the electroplating of third electroplated layer 78 entirely over the flanks 68, 70 of the leads 64, 62, respectively. This third electroplated layer 78, like the material of the first electroplated layer 52 and second electroplated layer 54, is composed of a solder wettable material. The ability to electroplate the flanks 68, 70 is created because the leads 64, 62, after etching of the material of the leadframe itself, are still electrically connected through the material of the second electroplated layer 54. In this way, the issues of smearing due to mechanical cutting of the flanks can be essentially eliminated, and a solder wettable material can be electroplated over the entire surface of the flanks 68, 70 in the form of the third electroplated layer 78. In effect, the material of the second electroplated layer 54 acts as a tie bar for the leads 64, 62 during the electroplating operation.

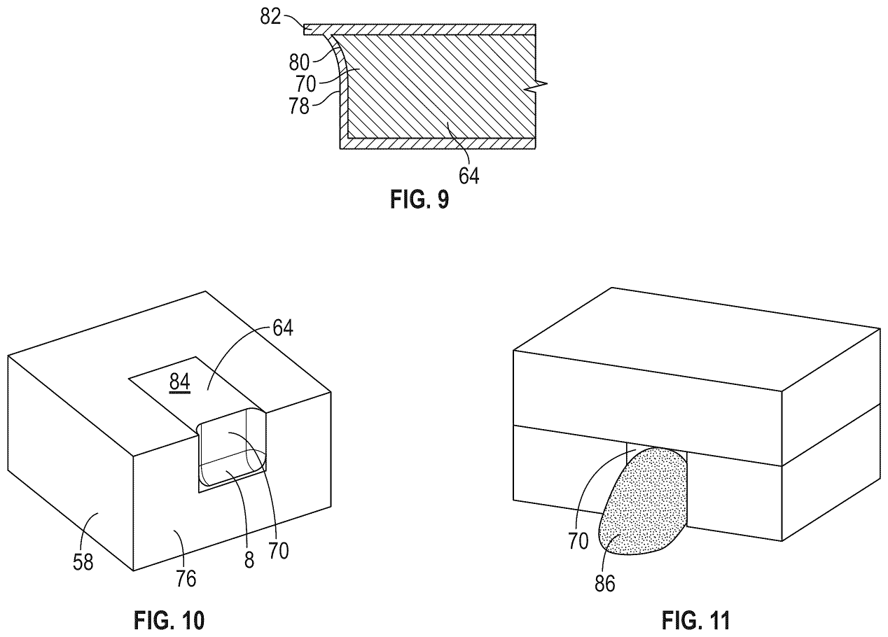

Referring to FIG. 8, semiconductor packages 72, 74 are illustrated following singulation of the mold compound 58 and the material of the second electroplated layer 54. As illustrated, the flanks 68, 70 are now exposed and recessed relative to surface 76 of the mold compound (relative to a plane formed by surface 76). FIG. 9 illustrates a detail view of lead 64 showing the shape of flank 70. Here, the shape of the third electroplated layer 78 includes a single curve 80 when viewed in cross section. The location where the third electroplated layer 78 and second electroplated layer 54 meet extends from the flank 70 forming a single flange 82. As illustrated in FIG. 9, the entire surface of flank 70 is covered by the third electroplated layer 78.

FIG. 10 illustrates a perspective view of the lead 64 that shows the resulting structure of the flank 70 in three dimensions including the curve 80 which extends along three sides of the flank 70. As evident by inspection of FIG. 10, the entire flank 70 is recessed relative to the surface 76 of the mold compound 58. The surface 84 of lead 64 that sits flush with the corresponding surface of the mold compound 58 is designed/configured to bond to the circuit board/motherboard during assembly with the semiconductor package. FIG. 11 shows the lead 64 of FIG. 10 flipped over following formation of a solder bond with the lead and illustrates how a fillet 86 of solder rises up the surface of the flank 70 to substantially (80%-95% or entirely wet the entire surface (100%) of the surface of the flank 70. In particular implementations, the height of the fillet 86 (as high as the flank) may also assist with ensuring better mechanical strength of the bond and may improve bond reliability over time. Furthermore, the presence of the curve in the shape of the flank may further aid with coupling of the fillet to the top area of the flank as the solder material wets the flank. With the fillet covering all or substantially all of the flank, the ability for optical recognition systems to detect the presence of the fillet is also increased, improving optical inspection quality and detection.

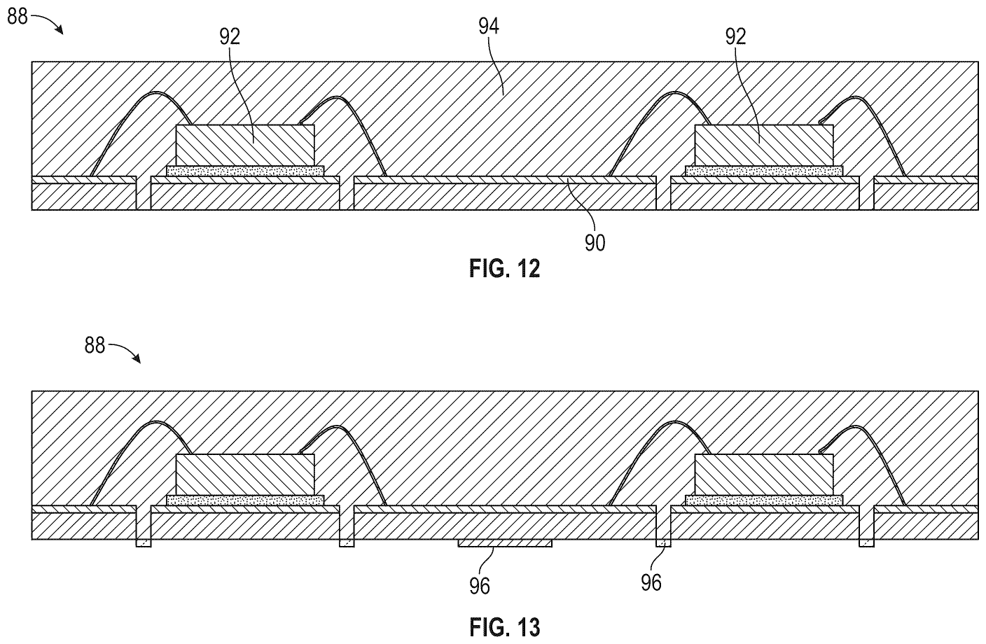

Referring to FIG. 12, a cross sectional view of an implementation of a leadframe 88 is illustrated following electroplating of a second electroplated layer 90 thereon, bonding of semiconductor die 92 thereto, wirebonding, and application of mold compound 94 thereon. The material of this leadframe and the mold compound may be any disclosed in this document and the semiconductor die may be any die type and substrate type disclosed in this document. Referring to FIG. 13, the leadframe 88 is illustrated following formation of a pattern 96 using a masking layer. As illustrated, the pattern 96 covers a portion of the exposed material of the leadframe 88.

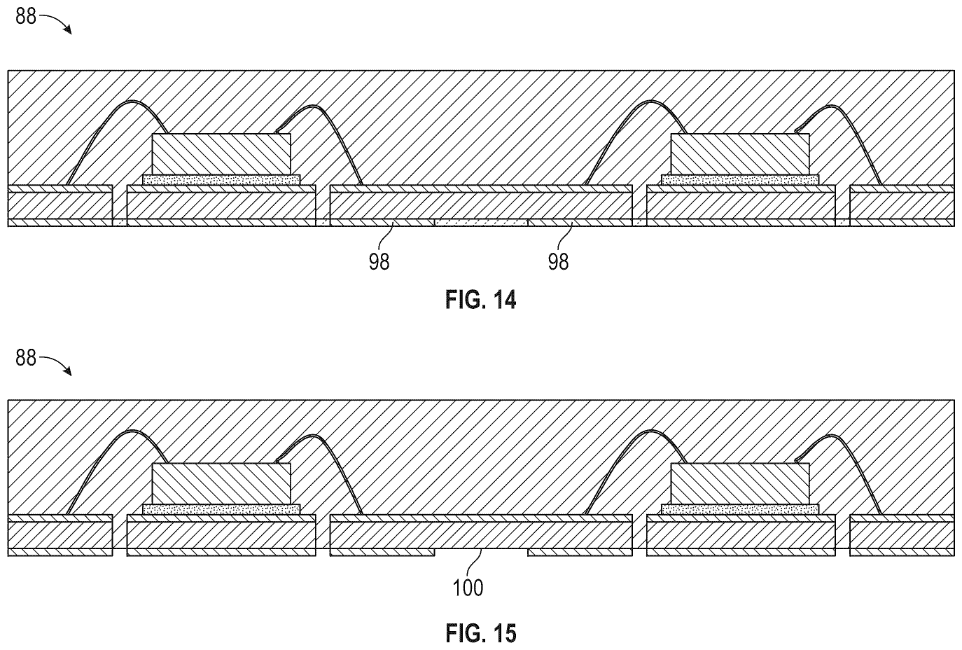

Referring to FIG. 14, the leadframe 88 of FIG. 13 is illustrating following the formation of a first electroplated layer 98 onto the exposed material of the leadframe 88. The pattern 96 prevents electroplating where it is located. The material of the first electroplated layer 98 and second electroplated layer 90 may be any solder wettable material disclosed in this document in various method implementations. FIG. 15 illustrates the leadframe 88 following removal of the masking layer that forms the pattern, which leaves an exposed area 100 of the material of the leadframe 88.

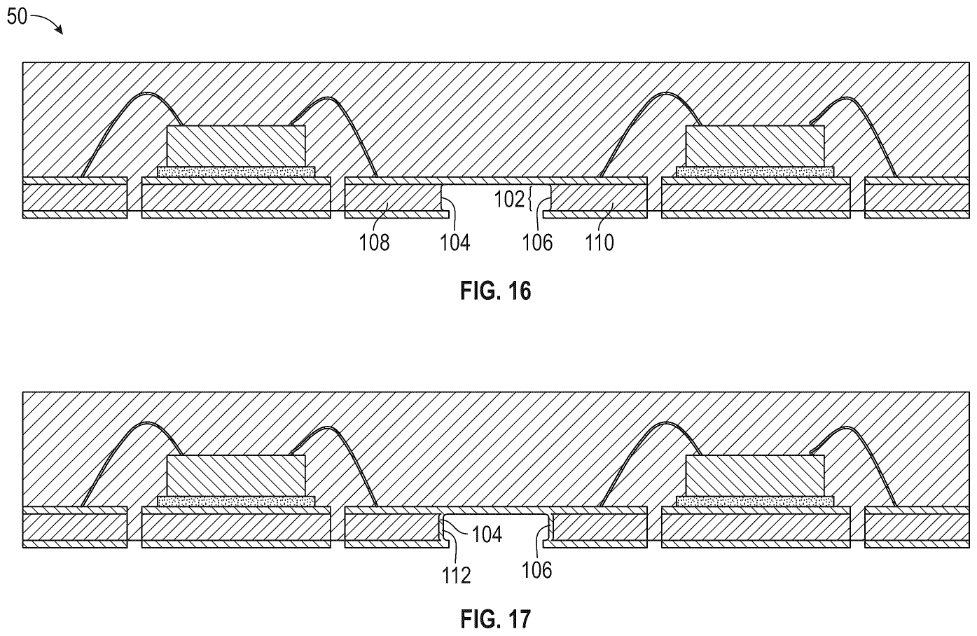

Referring to FIG. 16, the leadframe 88 of FIG. 15 is illustrated following removal of the material of the thickness 102 of the leadframe 88 using any removal method disclosed in this document consistent with the material of the leadframe 88. As illustrated in FIG. 16, if a removal method like wet etching is employed, the isotropic nature of the etch causes undercutting of the material of the leadframe 88 due to the selectivity of the etch to the material of the leadframe. The result of the removal process forms flanks 104, 106 of leads 108, 110. The material of the second electroplated layer 90 stops the removal process from fully separating the leads 108, 110, which allows the material of the second electroplated layer 90 to provide an electrical connection to the leads 108, 110.

FIG. 17 illustrates the leadframe 88 following electroplating of third electroplated layer 112 over the flanks 104, 106. As illustrated, like the method implementation previously described, because the flanks 104, 106 have been formed using a removal process like etching, any smearing from mechanical cutting is eliminated. Also, the ability to electroplate a solder wettable material as the third electroplated layer 112 completely across the flanks 104, 106 as illustrated in FIG. 17 greatly enhances the ability to form a fillet of solder completely across the surface of the flanks 104, 106.

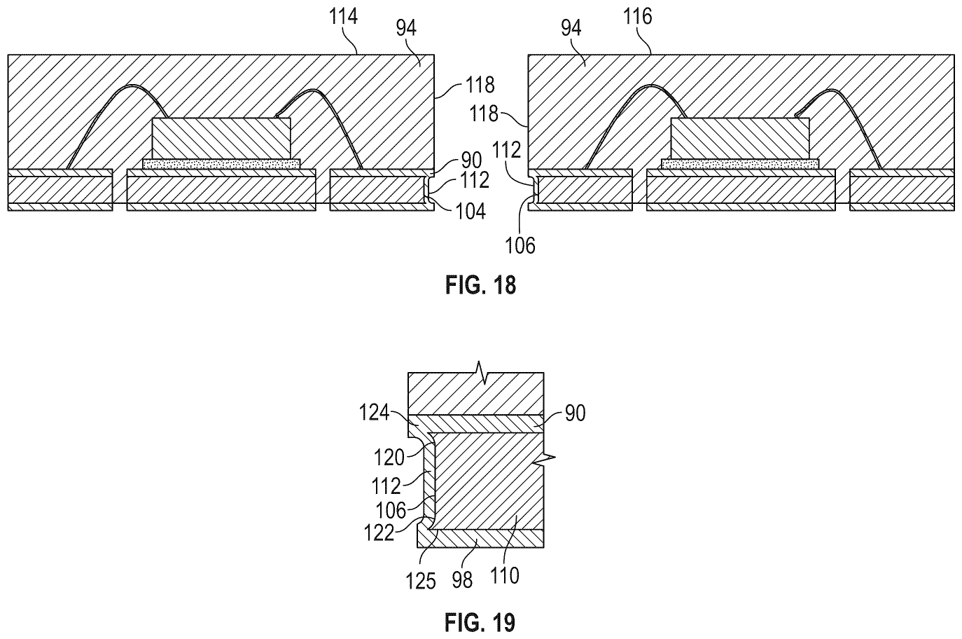

FIG. 18 illustrates semiconductor packages 114, 116 which have been formed following singulating of the material of the mold compound 94 and the second electroplated layer 90. Flanks 104, 106 are now exposed and recessed relative to a surface 118 of the mold compound/plane formed by surface 118 of the mold compound. The resulting shape of the flank 106 of lead 110 and third electroplated layer 112 is illustrated in in the detail cross sectional view of FIG. 19. Here, the shape of the flank 106 includes curves 120, 122 on each side of the lead that form a first flange 124 and second flange 125 that extend away from the material of the flank 106. In various package and method implementations, the flanges may also be formed in combination with the material of the third electroplated layer 112 and the first and second electroplated layers 98, 90, respectively.

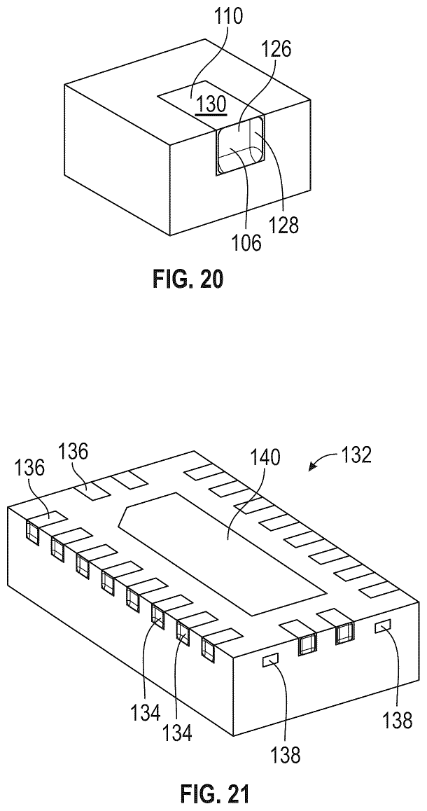

Viewed in three dimensions, as illustrated in FIG. 20 in the three dimensional view, the curves work to create a flank 106 with a recess 126 with a rounded edge 128 all the way around it that extends into the material of the lead 110. The flat portion 130 of the lead 110 is designed to form the bond with the circuit board/motherboard and the recess 126 of the flank formed by the flanges and covered with the solder wettable third electroplated layer is configured to help form a solder fillet across 100% of the flank 106 or substantially all of the flank 106 (85%-95%). An implementation of a resulting semiconductor package 132 with its leads is viewed in three dimensions in FIG. 21 which shows the flanks 134 and leads 136 along with tie bars 138 and die flag 140. As illustrated here, the flanks 134 are all recessed relative to the edge surface of the mold compound of the semiconductor package 132.

As illustrated in FIGS. 9 and 19, the flange that is adjacent to/includes the material of the second electroplated layer extends toward the surface of the mold compound further than the material of the flank on the opposite side of the lead (considerably further in the case of the lead implementation of FIG. 9. As illustrated, the second electroplated layer is applied to the surface of the lead that faces the circuit board/mother board and opposes the side of the lead that faces the semiconductor die.

While in the various flank implementations disclosed herein the presence of one or more curves and one or more flanges is illustrated, in those method implementations where the etch is anisotropic or more anisotropic, the flank may form a plane or substantially form a plane. In such implementations, the flank may still be recessed, but less so than in the implementations illustrated that include curve(s)/flange(s).

In places where the description above refers to particular implementations of semiconductor packages and implementing components, sub-components, methods and sub-methods, it should be readily apparent that a number of modifications may be made without departing from the spirit thereof and that these implementations, implementing components, sub-components, methods and sub-methods may be applied to other semiconductor packages.

What is claimed is:

1. A semiconductor package comprising:
one or more leads operatively coupled with one or more semiconductor devices; and
a mold compound coupled to the one or more leads and exposing a flank of the one or more leads through a surface of the mold compound that is oriented substantially perpendicularly to a longest length of the one or more leads;
wherein an exposed surface of the flank is recessed into the surface of the mold compound; and
wherein the exposed surface of the flank comprises at least one curve.

2. The semiconductor package of claim 1, wherein the at least one curve is adjacent to a plated surface of the lead facing the one or more semiconductor devices.

3. The semiconductor package of claim 1, wherein the at least one curve comprises an electroplated layer thereon.

4. The semiconductor package of claim 1, wherein a surface of the lead opposing a surface of the lead facing the one or more semiconductor devices comprises an electroplated layer thereon.

5. The semiconductor package of claim 1, wherein the exposed surface of the flank is completely covered by an electroplated layer thereon.

6. The semiconductor package of claim 4, wherein the electroplated layer of the surface of the lead opposing the surface of the lead facing the one or more semiconductor devices extends toward the surface of the mold compound further than the electroplated layer of the surface of the lead opposing the one or more semiconductor devices extends toward the surface of the mold compound.

7. The semiconductor package of claim 1, wherein an electroplated layer extending across the exposed surface of the flank forms a first flange on one side of the flank and a second flange on an opposing side of the flank.

8. The semiconductor package of claim 1, wherein an electroplated layer extending across the exposed surface of the flank forms a flange on one side of the flank.

9. A method of forming a wettable flank for a semiconductor package, the method comprising:
providing one or more leads operatively coupled with one or more semiconductor devices;
coupling a mold compound over the one or more leads;
exposing a portion of a leadframe through an opening in a first electroplated layer comprised on the leadframe;
forming an exposed flank of the one or more leads through etching a thickness of the leadframe to a second electroplated layer comprised on the leadframe; and
forming a third electroplated layer completely over the exposed flank of the one or more leads.

10. The method of claim 9, wherein forming the exposed flank further comprises recessing the exposed flank relative to a surface of the mold compound through the etching.

11. The method of claim 9, wherein forming the third electroplated layer completely over the exposed flank further comprises forming at least one flange in the third electroplated layer.

12. The method of claim 9, wherein forming the exposed flank further comprises forming at least one least one curve in the exposed flank.

13. The method of claim 9, further comprising forming two or more semiconductor packages by singulating the mold compound and the second electroplated layer.

14. The method of claim 9, wherein the second electroplated layer forms a tie bar to the one or more leads during the forming of the third electroplated layer.

15. A method of forming a wettable flank for a semiconductor package, the method comprising:
providing one or more leads operatively coupled with one or more semiconductor devices;
coupling a mold compound over the one or more leads;
masking an exposed portion of a leadframe with a masking layer;
forming a first electroplated layer on the exposed portion of the leadframe;
removing the masking layer;
forming an exposed flank of the one or more leads through etching a thickness of the leadframe to a second electroplated layer comprised on the leadframe; and
forming a third electroplated layer completely over the exposed flank of the one or more leads.

16. The method of claim 15, wherein forming the exposed flank further comprises forming two curves in the exposed flank.

17. The method of claim 15, wherein forming the third electroplated layer completely over the exposed flank further comprises forming two flanges in the third electroplated layer.

18. The method of claim 15, wherein forming the exposed flank further comprises recessing the exposed flank relative to a surface of the mold compound through the etching.

19. The method of claim 15, further comprising forming two or more semiconductor packages by singulating the mold compound and the second electroplated layer.

20. The method of claim 15, wherein the second electroplated layer forms a tie bar to the one or more leads during the forming of the third electroplated layer.
